(19) United States
(12) Patent Application Publication
(10) Pub. No.: US 2026/0289764 A1
(43) Pub. Date: Sep. 24, 2026

(54) METHOD FOR MEASURING DEFORMATION LEVEL OF CHIP AND METHOD FOR STACKING SEMICONDUCTOR CHIPS

(71) Applicant: NEXTIN, Inc., Hwaseong-si (KR)

(72) Inventors: Tae Hoon PARK, Yongin-si (KR); Junhee JEONG, Hwaseong-si (KR)

(21) Appl. No.: 19/458,917

(22) Filed: Jan. 25, 2026

(30) Foreign Application Priority Data
Jan. 24, 2025 (KR) 10-2025-0011462
Jan. 7, 2026 (KR) 10-2026-0002755

(51) Int. Cl. G06T 7/00; G01B 11/16; G06T 7/64

(52) U.S. Cl. CPC G06T 7/001; G01B 11/16; G06T 7/64; G06T 2207/20081; G06T 2207/30148

(57) ABSTRACT

Provided is a method for measuring a z-axis deformation level of a chip from a two-dimensional image of the chip, the method including: acquiring the two-dimensional image of the chip by scanning a surface of the chip; extracting a feature of the surface of the chip from the two-dimensional image; and measuring the z-axis deformation level of the chip based on the extracted feature.

### CROSS-REFERENCE TO RELATED APPLICATIONS

This application claims priority under 35 U.S.C. § 119 to Korean Patent Application No. 10-2025-0011462, filed on Jan. 24, 2025, in the Korean Intellectual Property Office, and Korean Patent Application No. 10-2026-0002755, filed on Jan. 7, 2026, in the Korean Intellectual Property Office, the disclosure of which is incorporated herein by reference in its entirety.

### TECHNICAL FIELD

The following disclosure relates to a method for measuring a deformation level of a semiconductor chip, and to a method for stacking semiconductor chips.

### BACKGROUND

A semiconductor chip (hereinafter, referred to as a chip) is manufactured by repeatedly performing unit processes such as film formation, etching, and metal wiring to form a fine pattern with an electrical property on a wafer. Inspection for defects is also rigorously performed during a manufacturing process due to high integration of a semiconductor device and a high process speed. This is because a partial defect of the fine pattern may directly lead to a failure of the semiconductor device.

During manufacturing and packaging processes, the semiconductor chip may experience z-axis deformation (bending or warpage) due to various thermal and mechanical stresses. For example, the chips previously bonded to each other on the wafer may undergo deformation such as warpage when being separated from each other during a sawing process, and a level of the deformation may vary from chip to chip.

The chip deformation may lead to an electrical contact failure, a package stacking failure, and degradation of reliability. Therefore, a technology for quantitatively measuring a deformation level of a chip surface is crucial for industrial applications.

Hitherto, the chip deformation has been measured using a contact displacement sensor, three-dimensional shape measurement equipment, interferometer-based equipment, or the like. However, such an approach involves high equipment costs or long measurement times, and has limitations in application to mass production lines.

Furthermore, in the case of a high bandwidth memory (HBM), which is manufactured by stacking semiconductor chips, problems such as a bonding failure and degradation of reliability during the process occur when deformation levels of the stacked chips are different from each other.

### SUMMARY

An embodiment of the present invention is directed to reducing an overall processing time compared to three-dimensional (3D) scanning and 3D image processing by estimating a z-axis deformation level of a chip based on a two-dimensional image.

An embodiment of the present invention is directed to reducing the processing time by measuring the z-axis deformation level using a geometric or optical feature that may reflect z-axis deformation of the chip.

An embodiment of the present invention is directed to improving reliability and productivity of a semiconductor process by measuring the deformation level before a stacking process and stacking chips with similar deformation levels.

Aspects of the present invention are not limited to the above-mentioned aspects. That is, other aspects that are not mentioned may be obviously understood by those skilled in the art from the following specification.

In one general aspect, a method for measuring a deformation level of a chip includes: acquiring a two-dimensional image of the chip by scanning a surface of the chip; extracting a feature of the surface of the chip from the two-dimensional image; and measuring a z-axis deformation level of the chip based on the extracted feature.

The extracting of the feature of the surface of the chip may include extracting geometric deformation of the surface of the chip from the two-dimensional image.

The extracting of the feature of the surface of the chip may include calculating a displacement value between a reference point on a reference image without deformation and a reference point in the acquired two-dimensional image.

The extracting of the feature of the surface of the chip may include: extracting a planar deformation model from the displacement value; and calculating a mean curvature value or a curvature energy value of the planar deformation model, and the z-axis deformation level of the chip is measured based on the mean curvature value or curvature energy value.

The extracting of the feature of the surface of the chip may include: setting, as the reference points, three or more points on a boundary of a specific region within the chip; and calculating an area or shape change amount of the specific region by comparing the displacement values of the reference points, and the z-axis deformation level of the chip is measured based on the calculated area or shape change amount.

The extracting of the feature of the surface of the chip may include: extracting optical brightness values for a plurality of regions included in the surface of the chip; and analyzing a contrast pattern of the surface of the chip based on a spatial distribution of the brightness values, and the spatial distribution of the brightness values changes depending on a change in surface inclination or reflected light caused by z-axis deformation of the chip.

The contrast pattern of the surface of the chip may be analyzed by comparing the brightness value of a central region of the chip with the brightness value of an edge region of the chip.

The z-axis deformation level may be predicted by a deep learning model, and the deep learning model may receive the acquired two-dimensional image and predict and output a z-axis deformation value of the chip.

A parameter of the deep learning model may be adjusted to minimize an error between a predicted value and an actual value of the deformation value by using a training data pair including the two-dimensional image of the chip and the deformation value associated with the z-axis deformation level of the chip, and the trained deep learning model may be configured to predict the z-axis deformation value of the chip by generalization also for a two-dimensional image of a chip that is not used for training.

In another general aspect, a device for measuring a deformation level of a chip includes: an image acquisition unit acquiring a two-dimensional image of the chip by scanning a surface of the chip; a feature extraction unit extracting a feature of the surface of the chip from the two-dimensional image; and a deformation calculation unit calculating a z-axis deformation level of the chip by using the extracted feature.

In another general aspect, a computer-readable recording medium stores instructions executed by a processor to acquire a two-dimensional image of a chip by scanning a surface of the chip, extract a feature of the surface of the chip from the two-dimensional image, and measure a z-axis deformation level of the chip based on the extracted feature.

In another general aspect, a method for stacking semiconductor chips includes: measuring the z-axis deformation level of each of a plurality of semiconductor chips; and grouping semiconductor chips with similar measured z-axis deformation levels and stacking the semiconductor chips belonging to the same group together.

### BRIEF DESCRIPTION OF THE DRAWINGS

FIG. 1A illustrates a reference point on a reference image for an undeformed chip.

FIG. 1B illustrates a reference point on a two-dimensional image obtained by scanning a deformed chip.

FIG. 1C illustrates displacement values (Δx, Δy) of each reference point.

FIG. 1D illustrates a graph of an exemplary planar deformation model according to the present disclosure.

FIG. 1E illustrates a comparison between z-axis deformation levels of multiple chips using mean curvatures H₁, H₂, and H₃ calculated from different planar deformation models (Model 1, Model 2, and Model 3).

FIG. 2 illustrates brightness changes of three chips with different deformation levels.

FIG. 3 is a diagram illustrating a state in which semiconductor chips are stacked.

### DETAILED DESCRIPTION OF MAIN ELEMENTS

1: Reference image
1′: Obtained two-dimensional image

### DETAILED DESCRIPTION OF EMBODIMENTS

Hereinafter, the present disclosure will be described in detail with reference to the drawings. However, this is merely exemplary, and the present disclosure is not limited to specific embodiments illustratively described.

A method for measuring a deformation level of a chip according to the present disclosure may include: acquiring a two-dimensional image of the chip by scanning a surface of the chip (S100); extracting a feature of the surface of the chip from the two-dimensional image (S200); and measuring a z-axis deformation level of the chip based on the extracted feature (S300).

According to the present disclosure, it is possible to reduce an overall processing time compared to three-dimensional (3D) scanning and 3D image processing by estimating the z-axis deformation level of the chip based on the two-dimensional image, which is advantageous.

The two-dimensional image of the chip used in the present disclosure may be acquired using various image sensors, such as a charge-coupled device (CCD)/complementary metal-oxide-semiconductor (CMOS) camera, a line scan camera, or an optical microscope. The image may be acquired under consistent lighting conditions, imaging distance, and imaging angle, and such conditions may be set such that brightness and pattern changes reflect a change in shape of the surface of the chip.

In the present disclosure, the term “feature” may be defined as including a geometric or optical feature that may reflect z-axis deformation of the chip. The geometric feature may include a displacement relative to a reference image, a strain, a curvature, and the like, and the optical feature may include brightness, contrast, a reflection pattern, and the like. Such features may be calculated through image processing techniques such as pixel value distribution within an image, and edge, corner, and feature point detection.

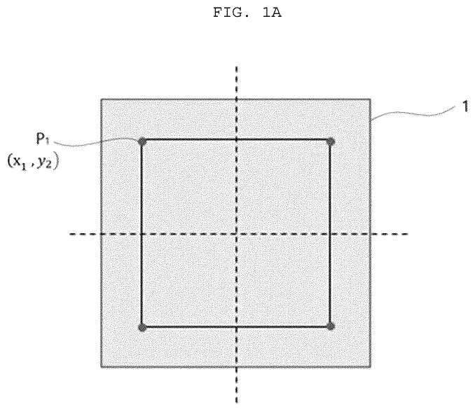

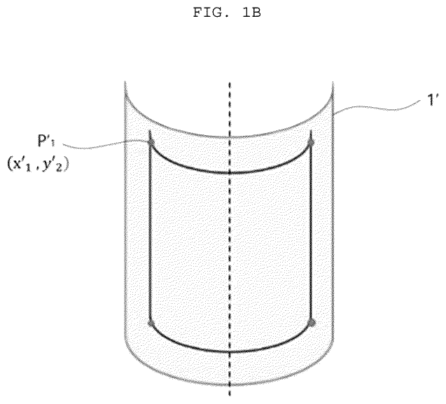

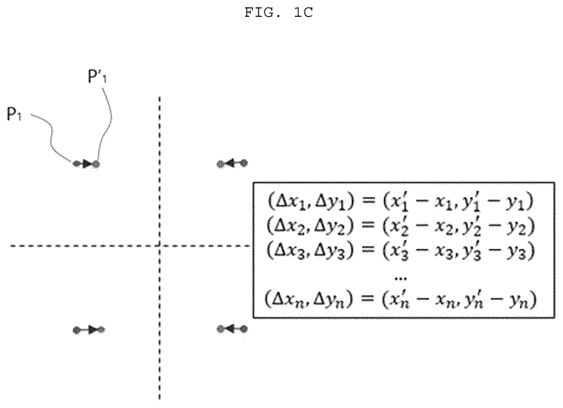

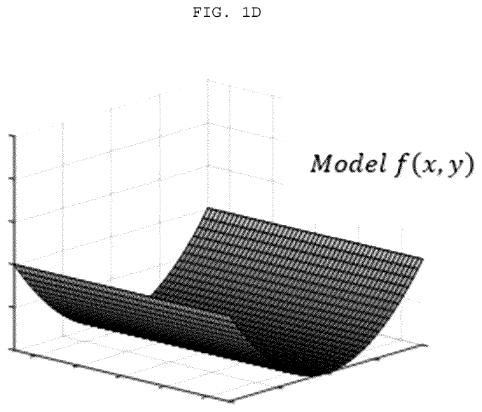

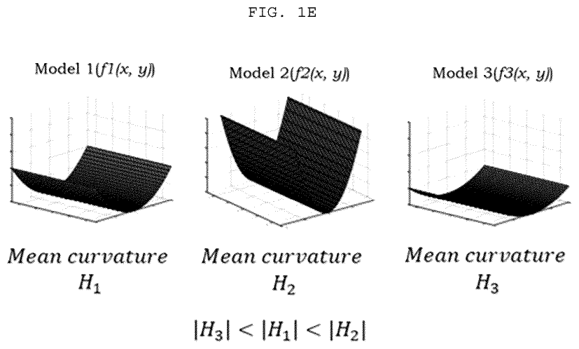

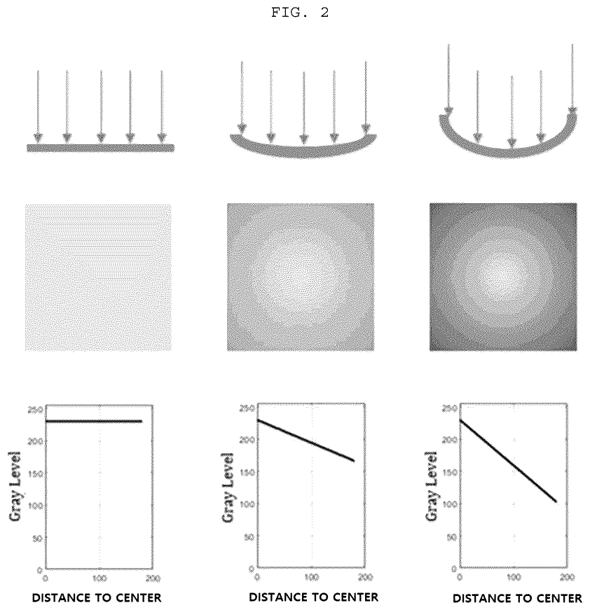

The following description will be made with reference to FIGS. 1A to 2.

According to the present disclosure, the extracting of the feature of the surface of the chip may include extracting geometric deformation of the surface of the chip from the two-dimensional image acquired by scanning the chip.

For example, the extracting of the feature of the surface of the chip may include calculating a displacement value between a reference point on a reference image without deformation and a reference point in the two-dimensional image acquired by scanning the chip.

The reference image without deformation may correspond to a two-dimensional image, and an image captured at an initial stage of manufacturing or a reference image stored in advance may be used as the reference image without deformation. A point detected through an image processing algorithm, such as a corner point, a feature point, or a pattern intersection point may be set as the reference point. It is preferable to set one or more reference points.

Reference point correspondence between the reference image and the acquired two-dimensional image may be performed using a feature point matching algorithm, such as scale-invariant feature transform (SIFT), speeded-up robust features (SURF), or oriented FAST and rotated BRIEF (ORB), or a deep-learning-based keypoint regression model. By doing so, displacement values (Δx, Δy) between a reference point P(x,y) on the reference image and a reference point P′(x′, y′) on the acquired two-dimensional image may be calculated.

FIGS. 1A to 1C are diagrams illustrating a process for calculating the displacement values. FIG. 1A illustrates a reference point P₁ on the reference image for an undeformed chip 1, FIG. 1B illustrates a reference point P′₁ on a two-dimensional image acquired by scanning a deformed chip 1′, and FIG. 1C illustrates the displacement values (Δx, Δy) of the respective reference points.

Furthermore, according to the present disclosure, the extracting of the feature of the surface of the chip may include extracting a planar deformation model from the displacement values and calculating a mean curvature value or a curvature energy value of the planar deformation model, and the z-axis deformation level of the chip may be measured based on the mean curvature value or curvature energy value.

Specifically, the displacement values (Δx=x′−x, Δy=y′−y) for each reference point may be used as displacement values reflecting local deformation of the chip. Using the displacement values extracted from multiple reference points, a planar deformation model (f(x, y)) may be constructed to approximate the deformation of the surface of the chip as a continuous curved surface.

Using the displacement of the reference point may enable construction of a two-dimensional displacement field of the surface of the chip, and the two-dimensional displacement field may be approximated by a polynomial curved surface or a nonlinear function model to extract the planar deformation model.

For example, the planar deformation model may be expressed in the following second-order polynomial form.

$$f ( x , y ) = {ax}^{2} + b {y}^{2} + c x y + dx + ey + f$$

Alternatively, a nonlinear-function-based model may also be applied to handle more complex deformations.

Since the displacement (Δx, Δy) of the reference point reflects a gradient of the model, an objective function (loss function) may be defined to minimize a difference between the measured displacement and the gradient predicted by the model, and coefficients a, b, c, d, e, and f of the model may be calculated by minimizing the objective function. In such an optimization process, least squares, a nonlinear optimization technique, or a regression-based learning technique may be applied.

Once the planar deformation model is calculated, a second-order derivative of f(x, y) may be used to calculate the mean curvature or curvature energy. Such a curvature-based metric may be used to quantitatively evaluate the z-axis deformation level of the surface of the chip or to compare the deformation levels across multiple chips or measurement regions.

FIG. 1D illustrates a graph of an exemplary planar deformation model according to the present disclosure, and FIG. 1E illustrates a comparison between the z-axis deformation levels of multiple chips using the mean curvatures H₁, H₂, and H₃ calculated from different planar deformation models (Model 1, Model 2, and Model 3).

As such, according to the present disclosure, the global degree of curvature of the chip may be calculated using the displacement of the reference points based on the two-dimensional image, thereby evaluating the z-axis deformation level.

Meanwhile, according to the present disclosure, the z-axis deformation level of the chip may also be evaluated based on an area or shape change of a specific region by using the displacement of the reference points.

According to the present disclosure, in the extracting of the feature of the surface of the chip, three or more points on a boundary of the specific region within the chip may be set as the reference points. Once the displacement values of each reference point are calculated, an area or shape change amount of the specific region may be calculated by comparing the displacement values of the reference points, and the z-axis deformation level of the chip may be measured based on the calculated area or shape change amount.

For example, a specific region A may be defined based on a region inside the chip that does not include a scribe line. At this time, edge points or corner points of an internal region of the chip may be set as reference points included in the region A, and such points may function as the reference points that may be stably tracked in images of the chip before and after sawing.

In the two-dimensional image of the undeformed chip, positions (x₁,y₁), (x₂,y₂), (x₃,y₃), and (x₄,y₄) of four reference points of the region A are stored, and in the image of the deformed chip, new positions (x₁′, y₁′), (x₂′, y₂′), (x₃′, y₃′), and (x₄′, y4_{′}) of the corresponding reference points may be detected. The displacement (Δx=x′−x, Δy=y′−y) of each reference point may reflect a characteristic of local deformation of the internal region of the chip, and the displacement value may be used to calculate change amounts of a width, a height, or a diagonal length of the region A.

Such a length change associated with a size of the region A or an angular change between the reference points vary depending on the degree of convex or concave deformation of the chip. Therefore, the values thereof may be used as indicators for quantitatively evaluating the z-axis deformation level of the chip.

For example, a pattern in which the width or height increases in a specific direction reflects an overall curvature direction of the surface of the chip, and a change in distance ratio between the corner points may indicate a strength and asymmetry of the deformation. Furthermore, as the shape change amount, for example, an angular change amount calculated by extracting the degree of inclination of a contour of the specific region may be reflected. The area change or shape change of the specific region defined in this way may be calculated using the individual displacement values of the reference point, the change in distance between the reference points (the width, the height, the diagonal length, and the like), the angular change between the reference points, and the like, which enables the measurement of the z-axis deformation level of the chip.

Meanwhile, in the present disclosure, the z-axis deformation level of the chip may be evaluated using a change in brightness or contrast within the image of the chip.

Such evaluation may be based on the principle that an optical change that occurs when the surface of the chip is deformed, such as a change in incident light, a shadow created when a deformed portion of the chip blocks light from an adjacent region, or a difference in amount of reflected light due to a change in surface inclination, causes a brightness change in the image.

According to the present disclosure, the extracting of the feature of the surface of the chip may include extracting optical brightness values for multiple regions included in the surface of the chip and analyzing a contrast pattern of the surface of the chip based on a spatial distribution of the brightness values. As described above, the brightness values for multiple regions may differ depending on a change in surface inclination or reflected light caused by z-axis deformation of the chip.

In a case where the chip is warped and causes the z-axis deformation, the brightness may vary across the entire image or at a partial region of the image due to a change in an angle at which the incident light reaches the surface, or a local shadow created by the edge or corner portion of the chip that deviates from an original position thereof and blocks light. Since such a brightness or contrast change caused by the deformation is associated with the z-axis deformation level of the chip, one or more values representing the change may be used to quantify the deformation level of the chip and compare the degree of deformation between the chips.

Various indicators representing the brightness or contrast change may be set. For example, a width of a shadow region, a gradient of a brightness change (profile) of a cross section of the shadow region, and a relative brightness difference between the center and the edge may be used. Such indicators may be defined or selected by a user, or a deep learning model may be used to automatically extract a brightness-based feature.

Meanwhile, the contrast pattern of the surface of the chip may be analyzed by comparing the brightness value of a central region of the chip with the brightness value of an edge region of the chip.

As a specific example, a chip warped such that a central portion is in close contact with a reference surface while four corners are lifted from the bottom is assumed.

In this case, when light is incident vertically from above, sufficient reflected light may reach a region in the vicinity of the center of the chip. However, as the distances to the corners decrease, the image may become darker due to a shadow caused by a surface gradient change and blocking of light.

In the acquired two-dimensional image, a linear path connecting center coordinates (x_center, y_center) of the chip and a corner point (x_corner, y_corner) to be analyzed may be set, and then brightness values (gray levels) of pixels along the path may be profiled in a linear or curved form to obtain a graph in which the brightness decreases toward the corner point.

In the brightness profile, a position of a point where the brightness falls below a preset threshold, a distance to the corner point, and a brightness gradient all reflect the contrast change caused by the chip deformation, and thus may be utilized as values for evaluating the z-axis deformation level of the chip.

FIG. 2 is a diagram illustrating the above example and illustrates the brightness changes for three chips with different deformation levels. The left side represents an undeformed chip, the center represents a slightly deformed chip, and the right side represents a significantly deformed chip.

The top three figures illustrate a state in which the incident light reaches the surface of each chip when viewed from the side. The middle three figures are two-dimensional images captured under identical optical conditions. The bottom three figures are graphs illustrating the brightness profiles along the path from the center to the corner of the image.

The chip on the left, which has no deformation, has nearly identical angles of light at the center and the edge. Therefore, it may be confirmed that there is almost no contrast pattern, and there is almost no gradient in the graph. On the other hand, the deformed chips exhibit different angles of light at the center and the corner. Therefore, it may be confirmed that a contrast pattern in which the image gradually becomes darker from the center toward the corner is observed, and the gradient in the graph increases as the deformation level increases.

The graph may enable identification of the brightness gradient in the graph and a distance from the corner point to a point where the brightness falls below a predefined threshold, and such values may represent the contrast change caused by the deformation and may be used to evaluate the z-axis deformation level.

As such, according to the present disclosure, the z-axis deformation level may be quantitatively calculated by linking optical changes of the chip with changes in the contrast distribution within the image, which may be utilized not only in a feature-based method but also in a deep-learning-based automatic feature extraction method.

According to the present disclosure, the z-axis deformation level of the chip may be directly predicted using a deep learning model. The deep learning model may receive the acquired two-dimensional image and predict and output a z-axis deformation value of the chip.

The method using deep learning is a method of training the deep learning model (hereinafter, referred to as a “model”) by using a training data pair including the two-dimensional image of the chip and a value associated with the deformation level of the chip, and causing the trained model to receive the two-dimensional image of the chip and predict and output the deformation level or a value associated therewith (hereinafter, referred to as a “deformation value”).

In a training process, the model may first receive the image of the chip included in training data and predict the deformation value. An error between a predicted value and an actual deformation value of the corresponding chip may be then calculated, and a weight and a parameter of the model are iteratively adjusted to reduce the error. The training may be performed until performance criteria (for example, loss, accuracy, and root mean squared error (RMSE)) set by the user are met.

During such a process, the model may learn a pattern, a correlation, a nonlinear variation, and the like between the image and the deformation value by itself, thereby ultimately forming a mapping for extracting the deformation value from the image within the model.

By applying appropriate normalization or data augmentation to prevent overfitting, the model may generalize a new chip image that is not used during the training process and accurately predict the deformation value of the corresponding chip.

Such a generalization ability of the deep-learning-based model allows for stable deformation level estimation even under diverse lighting conditions, diverse chip patterns, and manufacturing variations between chips.

Examples of a model structure may include a CNN-based network, a ResNet structure incorporating residual learning, or a vision transformer (ViT)-based structure for simultaneously reflecting a local pattern and an overall contour of a deformed region.

An output value of the model may be defined as various types of deformation values, such as an absolute value and a relative value of z-axis deformation, a curvature-based metric, and a displacement-based metric, and may be selected based on a format of the training data.

Furthermore, a loss function used in model training may be any one of methods commonly used in image-based regression problems, such as L1 (Lasso), L2 (MSE), and Huber loss, and the parameter of the model may be updated to minimize the loss function.

Therefore, a deep-learning-based prediction method has an advantage of being able to estimate the deformation level of the chip by using the entire image, without the need for a procedure of extracting a direct feature as a predefined feature point or a brightness value.

Meanwhile, the method for measuring a deformation level of a chip may be implemented in the form of a device including: an image acquisition unit acquiring the two-dimensional image of the chip by scanning the surface of the chip; a feature extraction unit extracting the feature of the surface of the chip from the two-dimensional image; and a deformation calculation unit calculating the z-axis deformation level of the chip by using the extracted feature.

Furthermore, the method for measuring a deformation level of a chip may be stored in a computer-readable recording medium in the form of a set of instructions, and a processor may execute the instructions to perform chip image acquisition, feature extraction, and deformation calculation.

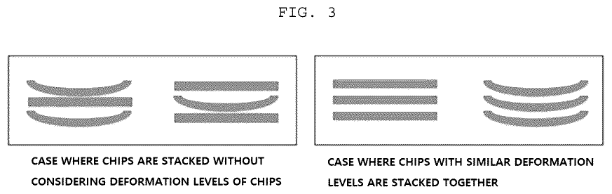

The method for measuring a deformation level of a chip according to the present disclosure has been described above. Hereinafter, a method for stacking semiconductor chips will be described with reference to FIG. 3.

In the method for stacking semiconductor chips according to the present disclosure, chips with similar deformation levels may be stacked together by using the above-described two-dimensional-image-based chip deformation level measurement technology and considering the deformation level of the chip in a process of stacking the semiconductor chips.

As illustrated on the left side of FIG. 3, in a case where a difference in z-axis deformation (warpage) between the chips is significant during semiconductor packaging or 3D stacking processes, various reliability issues may arise, such as increased internal stress within a package, interfacial imbalance between the chips, stacked structure deformation, and bonding failures. Therefore, as illustrated on the right side of FIG. 3, measuring the z-axis deformation level of each chip before stacking the chips, grouping the chips with similar deformation levels, and stacking the chips within the same group effectively ensure stability and reliability of the overall stacked structure.

According to the present disclosure, the method may include measuring the z-axis deformation level of each of a plurality of semiconductor chips, grouping semiconductor chips with similar measured z-axis deformation levels, and stacking the semiconductor chips belonging to the same group together.

The deformation value representing the z-axis deformation level may be a single scalar value, or may include a feature vector including various values such as the mean curvature value, curvature energy value, and brightness-based graph gradient of each chip.

Once the deformation values of the chips are obtained, differences or similarities in deformation level between the chips may be quantitatively compared. For example, in a case where the difference in deformation value between two chips is equal to or less than a preset threshold, the chips may be determined to have identical deformation characteristics. Alternatively, the similarity in deformation may be determined by applying various quantitative criteria such as a root mean square (RMS)-based criterion and a curvature gradient-based criterion. The chips may be classified into one or more groups based on the similarity in deformation value, and the chips with identical or similar deformation levels may be grouped together.

The grouped chips may be stacked by group, so that the chips belonging to the same group are arranged continuously, thereby minimizing deformation imbalance within the stacked structure.

For example, significantly deformed chips may be grouped together, or slightly deformed chips may be stacked together, thereby ensuring uniform package flatness and avoiding inappropriate combinations of chips with opposite deformation directions or large curvature differences.

According to the present disclosure, it is possible to improve package surface flatness, achieve a uniform chip stress distribution, and ensure long-term reliability.

According to an embodiment of the present invention, it is possible to reduce an overall processing time compared to 3D scanning and 3D image processing by estimating the z-axis deformation level of the chip based on a two-dimensional image.

Further, it is possible to improve reliability and productivity of a semiconductor process by measuring the deformation level before a stacking process and stacking chips with similar deformation levels.

Effects of the present invention are not limited to the abovementioned effects, and effects that are not mentioned will be clearly understood by those skilled in the art to which the present invention pertains from the present specification and the accompanying drawings.

Although embodiments of the present invention have been described hereinabove with reference to the accompanying drawings, those skilled in the art to which the present invention pertains will be able to understand that the present invention may be implemented in other specific forms without departing from the spirit or essential feature of the present invention. Therefore, it is to be understood that embodiments described hereinabove are illustrative rather than being restrictive in all aspects.

What is claimed is:

1. A method for measuring a deformation level of a chip, the method comprising:
acquiring a two-dimensional image of the chip by scanning a surface of the chip;
extracting a feature of the surface of the chip from the two-dimensional image; and
measuring a z-axis deformation level of the chip based on the extracted feature.

2. The method of claim 1, wherein the extracting of the feature of the surface of the chip includes extracting geometric deformation of the surface of the chip from the two-dimensional image.

3. The method of claim 2, wherein the extracting of the feature of the surface of the chip includes calculating a displacement value between a reference point on a reference image without deformation and a reference point in the acquired two-dimensional image.

4. The method of claim 3, wherein the extracting of the feature of the surface of the chip includes:
extracting a planar deformation model from the displacement value; and
calculating a mean curvature value or a curvature energy value of the planar deformation model, and
the z-axis deformation level of the chip is measured based on the mean curvature value or the curvature energy value.

5. The method of claim 3, wherein the extracting of the feature of the surface of the chip includes:
setting, as the reference points, three or more points on a boundary of a specific region within the chip; and
calculating an area or shape change amount of the specific region by comparing the displacement values of the reference points, and
the z-axis deformation level of the chip is measured based on the calculated area or shape change amount.

6. The method of claim 1, wherein the extracting of the feature of the surface of the chip includes:
extracting optical brightness values for a plurality of regions included in the surface of the chip; and
analyzing a contrast pattern of the surface of the chip based on a spatial distribution of the brightness values, and
the spatial distribution of the brightness values changes depending on a change in surface inclination or reflected light caused by z-axis deformation of the chip.

7. The method of claim 6, wherein the contrast pattern of the surface of the chip is analyzed by comparing the brightness value of a central region of the chip with the brightness value of an edge region of the chip.

8. The method of claim 1, wherein the z-axis deformation level is predicted by a deep learning model, and the deep learning model receives the acquired two-dimensional image and predicts and outputs a z-axis deformation value of the chip.

9. The method of claim 8, wherein
a parameter of the deep learning model is adjusted to minimize an error between a predicted value and an actual value of the deformation value by using a training data pair including the two-dimensional image of the chip and the deformation value associated with the z-axis deformation level of the chip, and
the trained deep learning model is configured to predict the z-axis deformation value of the chip by generalization also for a two-dimensional image of a chip that is not used for training.

10. A device for measuring a deformation level of a chip, the device comprising:
an image acquisition unit acquiring a two-dimensional image of the chip by scanning a surface of the chip;
a feature extraction unit extracting a feature of the surface of the chip from the two-dimensional image; and
a deformation calculation unit calculating a z-axis deformation level of the chip by using the extracted feature.

11. A method for stacking the chips according to claim 1, the method comprising:
measuring the z-axis deformation level of each of a plurality of semiconductor chips; and
grouping semiconductor chips with similar measured z-axis deformation levels and stacking the semiconductor chips belonging to the same group together.
